(19) United States
(12) Patent Application Publication
(10) Pub. No.: US 2013/0094160 A1
(43) Pub. Date: Apr. 18, 2013

(54) DISPLAY DEVICE

(71) Applicant: Japan Display East Inc., Mobara-shi (JP)

(72) Inventor: Tooru NARUMI, Mobara-shi (JP)

(73) Assignee: Japan Display East Inc., Mobara-shi (JP)

(21) Appl. No.: 13/650,272

(22) Filed: Oct. 12, 2012

(30) Foreign Application Priority Data
Oct. 14, 2011 (JP) 2011-227286

(51) Int. Cl. H05K 7/14

(52) U.S. Cl. 361/752

(57) ABSTRACT

The present invention is a display device where it is possible to prevent, at a high level, an adhesive from protruding to the metal frame for supporting the display panel in the case where the front window is pasted to the display panel via the adhesive. Specifically, the present invention provides a display device having; a display panel LCP; a metal frame FR1 for supporting the display panel; and a front window FW pasted to a front of the display panel using an adhesive AD, characterized in that the front window is provided so as to cover part of a front of the metal frame, and a containing portion HL for containing the adhesive that overflows from a space between the display panel and the front window is created in an area, which is part of the metal frame and is covered by the front window.

### CROSS-REFERENCE TO RELATED APPLICATION

The present application claims priority over Japanese Patent Application JP2011-227286 filed on Oct. 14, 2011, the contents of which are hereby incorporated into this application by reference.

### BACKGROUND OF THE INVENTION

(1) Field of the Invention

The present invention relates to a display device, and in particular, to a display device having a front window, such as a protective glass or a touch panel, on the front side of the display panel.

(2) Description of the Related Art

Various types of display devices, such as liquid crystal modules (liquid crystal display devices) and organic electroluminescent display devices, have been used as the display devices for many portable information apparatuses, such as cellular phones, personal digital assistants (PDAs), digital cameras and multimedia players.

In recent years, various types of front windows have been provided on the front of the display panel of the display devices, for example, a touch panel is provided as an input device for various types of apparatuses or a protective glass is provided in order to protect the display surface. JP 2009-8703A discloses a structure where a transparent plate, which is a front window, is provided on the front of a liquid crystal display device.

FIG. 1 is a cross-sectional diagram showing an example where a front window FW is pasted to the front surface of a liquid crystal display device. The front window FW and the liquid crystal display panel LCP are pasted together using an adhesive AD. The liquid crystal display panel LCP is formed of two transparent substrates (first substrate SUB1 and second substrate SUB2) that sandwich a liquid crystal layer and polarizing plates (PP1, PP2) placed on the outside thereof. The adhesive AD is uniformly applied to the entire surface on the upper side of the polarizing plate PP1 of the liquid crystal display panel LCP so that the liquid crystal display panel LCP and the front window FW are tightly pasted together.

In addition, display devices are supported by a metal frame when the display device is mounted in a housing for a certain apparatus, and as shown in FIG. 1, the metal frame FR1 is joined to a liquid crystal display panel LCP using an adhesive tape AT1. Here, a backlight BL is provided on the lower side of the liquid crystal display panel LCP and is fixed to the liquid crystal display panel LCP using an adhesive tape AT2 or the like. The liquid crystal display panel LCP and the backlight are contained in another frame FR2, and the metal frame FR1 is engaged with and covers the frame FR2.

A transparent liquid adhesive that has a high level of fluidity and is cured with ultraviolet rays or heat is used as the adhesive for pasting the display panel and the front window together. Liquid adhesives cause such problems that they easily enter into spaces, and thus enter into the space between the liquid crystal display panel LCP and the metal frame FR1, and the adhesive that has entered in that way cannot be cured, or the amount of adhesive for use is large. In order to solve the problems, JP 2009-8703A discloses a resin film, such as an adhesive tape AT1 that is provided between the display panel and the metal frame and surrounds the display panel.

### SUMMARY OF THE INVENTION

When a front window, such as a protective glass or a touch panel, is pasted to a display panel, such an amount of adhesive as to be required to form an adhesive layer having a sufficient thickness is applied in order to prevent bubbles from being created in the adhesive layer between the front window and the display panel. As shown in FIG. 2, such a problem arises that the adhesive AD protrudes from the sides of the front window and the display panel that have been pasted together before the adhesive is cured. The symbol FPC in FIG. 2 denotes a flexible printed circuit for electrical connection to the liquid crystal display panel LCP or the light source for the backlight (light emitting diodes).

The adhesive that has protruded from the front window FW adheres to the metal frame FR1, causing the following problems.

(1) The adhesive prevents the metal frame from being pasted to the housing of a certain apparatus.
(2) The protruding adhesive is peeled through friction with the housing of a certain apparatus so as to create a foreign substance.
(3) In the case where the adhesive is wiped off or removed, the efficiency in the work is poor and it takes time. In particular, in the case where the surface of the metal frame has been painted, it is difficult to wipe the adhesive off because no solvent can be used.

When the display device is assembled into a certain apparatus, such as a cellular phone, a portable information terminal, a digital camera or a multimedia player, the front of the metal frame of the display device is pasted to the inside of the housing of the apparatus using an adhesive tape so that a foreign substance can be prevented from entering. However, it is necessary to prevent the adhesive from protruding to the metal frame in order to secure the area of the front of the metal frame through which the display device and the apparatus are pasted together when the apparatus is a product with a narrow frame resulting from a reduction in the size of the apparatus.

Furthermore, as shown in JP 2009-8703A or FIG. 1, there are no places to which the extra adhesive can avoid, which makes the possibility of the adhesive protruding to the metal frame FR1 higher in the case where the adhesive sheet AT1 between the metal frame FR1 and the liquid crystal display panel LCP prevents the adhesive from entering into the space between the metal frame and the liquid crystal display panel.

An object of the invention is to solve the above-described problems and to provide a display device where it is possible to prevent, at a high level, the adhesive from protruding to the metal frame for supporting the display panel, even in the case where the front window is pasted to the display panel via an adhesive.

The display device according to the present invention has the following features in the structure in order to solve the above-described problems.

(1) A display device having; a display panel; a metal frame for supporting the display panel; and a front window pasted to a front of the display panel using an adhesive, is characterized in that the front window is provided so as to cover part of a front of the metal frame, and a containing portion for containing the adhesive that overflows from a space between the display panel and the front window is created in an area, which is part of the metal frame and is covered by the front window.
(2) The display device according to (1) is characterized in that the display panel and the metal frame are joined together using an adhesive tape surrounding the front of the display panel, the containing portion is a through hole created in the metal frame, and the adhesive tape is provided so as to cover one opening of the through hole.
(3) The display device according to (1) or (2) is characterized in that a surface of the metal frame on the front window side is painted.

According to the present invention, the front window is provided so as to cover part of a front of the metal frame, and a containing portion for containing the adhesive that overflows from a space between the display panel and the front window is created in an area, which is part of the metal frame and is covered by the front window, and therefore, it is possible to prevent such a harmful effect that the adhesive protrudes from the front window and adheres to the metal frame.

In addition, the display panel and the metal frame are joined together using the adhesive tape surrounding the front of the display panel, the above-described containing portion is a through hole created in the metal frame, and the adhesive tape is provided so as to cover one opening of the through hole, and therefore, no such problem arises that the adhesive contained in the containing portion enters into a space between the metal frame and the display panel.

In the case where the surface of the metal frame on the front window side is painted, the display device according to the present invention makes it possible to prevent such a problem that the paint comes off because the adhesive is prevented from protruding, which makes the wiping off or removal unnecessary.

### BRIEF DESCRIPTION OF THE DRAWINGS

FIG. 1 is a cross-sectional diagram schematically showing a conventional display device;

FIG. 2 is a plan diagram showing the display device in FIG. 1 for illustrating how the adhesive protrudes from the front window;

FIG. 3 is a cross-sectional diagram schematically showing the display device according to the present invention;

FIG. 4 is a plan diagram showing an example of the metal frame used in the display device according to the present invention; and

FIG. 5 is a cross-sectional diagram showing another example of the metal frame used in the display device according to the present invention.

### DESCRIPTION OF THE EMBODIMENTS

The display device according to the present invention is described in detail below.

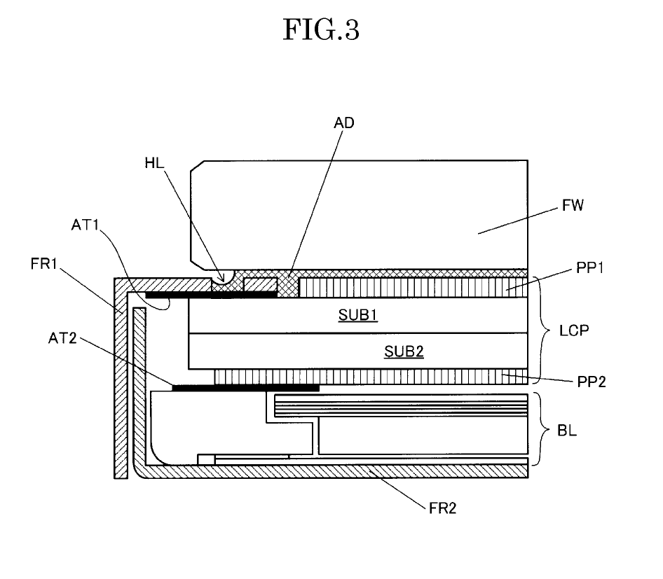

As shown in FIG. 3, the present invention provides a display device having: a display panel LCP; a metal frame FR1 for supporting the display panel; and a front window FW pasted to a front of the display panel using an adhesive AD, characterized in that the front window FW is provided so as to cover part of a front of the metal frame FR1, and a containing portion HL for containing the adhesive that overflows from a space between the display panel LCP and the front window FW is created in an area, which is part of the metal frame FR1 and is covered by the front window FW.

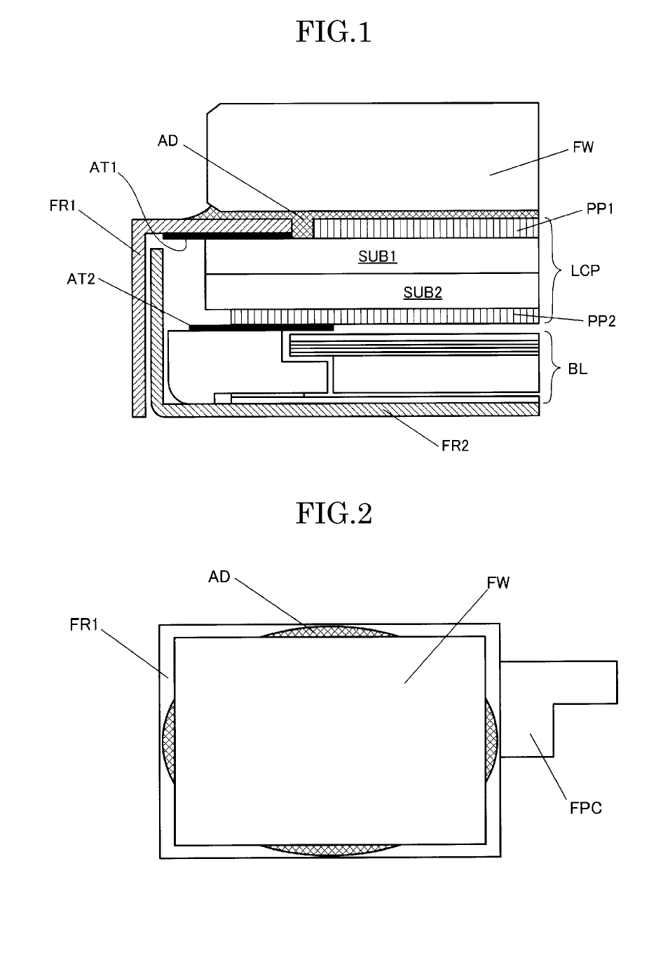

The display panel used in the display device according to the present invention is not limited to the liquid crystal display panel shown in FIG. 3, and it is possible to use various types of display panels, such as organic electroluminescent display panels. In addition, the front window pasted to the display panel is not limited to a transparent plate, such as a protective glass, and may be a touch panel or a complex member to which a touch panel has been pasted in advance. In addition, the members shown in FIG. 3 are the same as those in FIG. 1, and the descriptions thereof are omitted.

The adhesive for joining the front window and the display panel together is a transparent liquid adhesive having a high level of fluidity, and heat curing or photo-setting adhesives are appropriate for use.

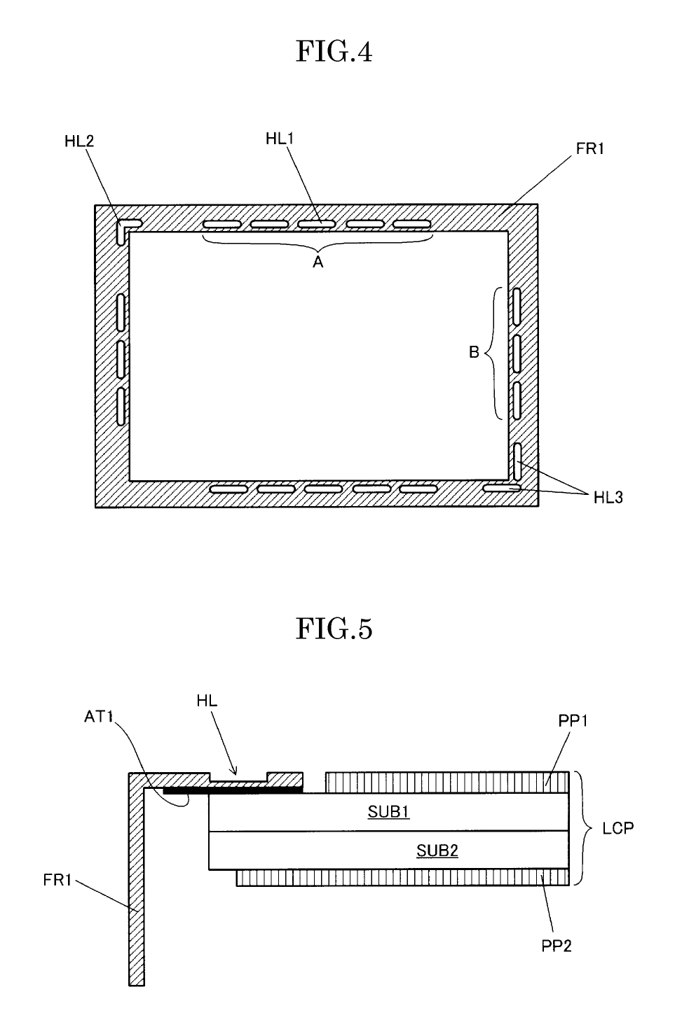

The display device according to the present invention is characterized in that a containing portion HL for containing an adhesive is provided in part of the metal frame FR1. FIG. 4 is a plan diagram showing the metal frame FR1, where the symbols HL1 to HL3 denote containing portions.

The containing portions HL may be through holes that penetrate through the metal frame as in FIG. 3 or may be recesses in the metal frame on the front window side as in FIG. 5. When the containing portions are created as through holes, it is necessary to clog the through holes on the display panel side in order to prevent such a problem as that the adhesive enters into a space between the metal frame FR1 and the display panel LCP through the containing portions, and in order to increase the ease of repairing. When an adhesive tape for joining the display panel and the metal frame together is used as shown in JP 2009-8703A, the number of members to be used can be reduced so that it is possible to prevent the manufacturing costs from increasing and the manufacturing process from becoming more complex.

The containing portions HL may be located anywhere in the area that is covered by the front window FW as shown in FIG. 3. In addition, as shown in FIG. 2, the adhesive AD easily protrudes, particularly in the center portions of each side for defining the form of the display panel. Therefore, as shown in FIG. 4, it is preferable to create the containing portions mainly at the center of each side or collectively in the vicinity of the center of each side.

In the case where the containing portions are recesses, the containing portions located along the sides may have any length and the containing portions located in the corners may have any form. In the case where the containing portions are through holes, it is necessary to take into consideration the prevention of reduction in the mechanical strength of the metal frame FR1. For example, it is preferable from the point of view of strength to provide a greater number of short containing portions HL1 as shown in FIG. 4 instead of creating a smaller number of long containing portions. Alternatively, it is preferable to arrange a greater number of narrow containing portions in parallel instead of providing a smaller number of broad containing portions (in terms of the width in the direction perpendicular to the sides), and in particular, it is preferable to stagger them. Furthermore, as for the form of the containing portions in the corners, a number of containing portions HL3 combined in a corner provides higher mechanical strength than one containing portion HL2 that continues in a corner as shown in FIG. 4.

The volume of the required containing portions is calculated below for reference. In the case where the layer thickness of the adhesive AD between the front window FW and the display panel LCP needs to be 0.070 mm, the amount of application required to cover the display surface of the front window FW (45.9 m×60.9 mm) is 195.7 mm³. Due to the space between the polarizing plate PP1 and the metal frame, an adhesive of approximately 36.3 mm³ is stored. Therefore, the total of tolerable adhesive is 232.0 mm³.

In contrast to this, in the case where the dispersion of the amount of adhesive to be applied is +/−10% of the target value, the target value of the amount of application is set to the 100/90 times higher than the required amount of application (217.4 mm³) in order for the required amount of application to be the lower limit (90%). At this time, the maximum amount of application is 110% of the target value (239.2 mm³), which exceeds the tolerable amount of application by 7.2 mm³.

This excess adhesive protrudes to the metal frame FR1 from the sides according to the prior art. In the case where the metal frame has a thickness of 0.15 mm according to the present invention, through holes of 48 mm² are provided in the vicinity of the places where protrusion occurs are containing portions for securing the adhesive of 7.2 mm³ that has exceeded the required amount of application, and thus, it is possible to prevent the adhesive from protruding.

The display device according to the present invention is appropriate for use as the display device having a front window FW or an upper metal frame FR1, and in particular is highly effective in the case where there is an area where the front window FW overlaps the metal frame FR1 where the front window FW is smaller than the outer shape of the display device (outer shape of the metal frame). In the case where the surface of the metal frame FR1 on the front window FW side is painted, it is difficult to remove the protruding adhesive with a solvent, and therefore, it is more preferable to use the structure of the present invention.

In addition, the adhesive can be prevented from protruding from the metal frame, and therefore, it is possible to finely adjust the location where the front window is pasted as compared to the method of pasting an adhesive sheet according to which no adhesive generally protrudes before the adhesive is cured after the front window has been pasted, and thus, pasting with high precision can be easily implemented.

FIG. 5 is a cross-sectional diagram showing another example of the present invention. FIG. 5 only shows a metal frame FR1, a display panel LCP and an adhesive tape AT1 provided between the first substrate SUB1 and the metal frame of the display panel. The structure of the other parts of the display device is the same as in FIG. 3, and therefore is not shown. A containing portion HL for containing an adhesive is provided in part of the metal frame FR1. In FIG. 5, the display device is different from that in FIG. 3 in that the containing portion HL is not a through hole but a recess provided on the front window side. Since the containing portion HL has a bottom, no such problem arises that the adhesive enters into a space between the metal frame FR1 and the display panel LCP through the containing portion irrelevant of the location of the adhesive tape.

As described above, the present invention can provide a display device where it is possible at a high level to prevent the adhesive from protruding to the metal frame for supporting the display panel, even in the case where the front window is pasted to the display panel via an adhesive.

What is claimed is:

1. A display device, comprising: a display panel; a metal frame for supporting the display panel; and a front window pasted to a front of the display panel using an adhesive, characterized in that
the front window is provided so as to cover part of a front of the metal frame, and
a containing portion for containing the adhesive that overflows from a space between the display panel and the front window is created in an area, which is part of the metal frame and is covered by the front window.

2. The display device according to claim 1, characterized in that
the display panel and the metal frame are joined together using an adhesive tape surrounding the front of the display panel,
the containing portion is a through hole created in the metal frame, and
the adhesive tape is provided so as to cover one opening of the through hole.

3. The display device according to claim 1 or 2, characterized in that
a surface of the metal frame on the front window side is painted.
